(19) United States
(12) Patent Application Publication
(10) Pub. No.: US 2017/0159837 A1
(43) Pub. Date: Jun. 8, 2017

(54) RUBBER-LAMINATED SEALING VALVE

(71) Applicant: NOK Corporation, Tokyo (JP)

(72) Inventor: Akiko KOGA, Kanagawa (JP)

(21) Appl. No.: 15/324,102

(22) PCT Filed: Jul. 9, 2015
(86) PCT No.: PCT/JP2015/069718

§ 371 Date: Jan. 5, 2017

(30) Foreign Application Priority Data
Jul. 9, 2014 (JP) 2014-141420

(51) Int. Cl. F16K 25/00; C23C 16/26; C23C 16/50

(52) U.S. Cl. CPC F16K 25/005; C23C 16/50; C23C 16/26

(57) ABSTRACT

A rubber-laminated sealing valve comprising a fluororubber layer and an amorphous carbon film that are sequentially laminated, wherein the amorphous carbon film is formed by a CVD plasma treatment method that supplies a high-frequency power from a high-frequency power source using hydrocarbon gas. The rubber-laminated sealing valve forms an amorphous carbon film having an indenter hardness of 5 GPa or more (corresponding to a Vickers hardness of about Hv 500 or more; when converted by Hv (kg/m²)=HIT (MPa)×0.0926 according to ISO 14577-1) on the surface of a rubber layer, wherein the rubber layer is non-adhesive to a mating material.

### TECHNICAL FIELD

The present invention relates to a rubber-laminated sealing valve. More particularly, the present invention relates to a rubber-laminated sealing valve that satisfies non-adhesiveness required for sealing valves.

### BACKGROUND ART

Rubber is laminated on the surface of a valve intended for sealing. Because rubber is an elastic body, it facilitates sealing, while it is easy to stick to other materials. In a sealing valve that has not been opened and closed for a long period of time, the rubber layer may be anchored to the mating material. In that case, it is difficult to open and close the valve. Further, a valve that has been repeatedly opened and closed may be affected by the height of the frictional coefficient of the rubber layer, and may be worn out due to the abrasion with the mating material.

For the purpose of preventing these phenomena, surface treatment or coating treatment is generally performed on the surface of a rubber layer in order to impart non-adhesiveness and slipping properties.

In Patent Documents 1 to 3, surface treatment is performed using fluororesin, such as PTFE resin, to impart non-adhesiveness. In these cases, however, there is a concern that sealing properties cannot be ensured depending on the film thickness, because the fluororesin is not an elastic body. In Patent Documents 4 to 7, non-adhesiveness is imparted by coating with silicon or silicone; however, there is a concern for poor contact caused by siloxane to be generated due to the recent trend of miniaturization of products. Thus, there is an increasing demand for silicon-free coating.

Furthermore, in Patent Document 8, a diamond-like carbon layer having a Vickers hardness of Hv 50 to 500 is formed on the surface of a rubber layer to impart non-adhesiveness; however, a higher hardness is desirable in order for a valve to exhibit non-adhesiveness by diamond-like carbon.

### PRIOR ART DOCUMENTS

### Patent Documents

Patent Document 1: JP-B-1398233

Patent Document 2: JP-A-10-9422

Patent Document 3: JP-B-3821887

Patent Document 4: JP-B-4278055

Patent Document 5: JP-B-4553697

Patent Document 6: JP-B-4553698

Patent Document 7: JP-A-2004-60832

Patent Document 8: JP-A-2006-258283

Patent Document 9: JP-A-8-104789

Patent Document 10: JP-A-8-120144

Patent Document 11: JP-A-8-120146

Patent Document 12: JP-A-8-143535

Patent Document 13: JP-A-2008-31195

### OUTLINE OF THE INVENTION

### Problem to Be Solved By the Invention

An object of the present invention is to provide a rubber-laminated sealing valve in which an amorphous carbon film having an indenter hardness of 5 GPa or more (corresponding to a Vickers hardness of about Hv 500 or more; when converted by Hv (kg/m²)=HIT (MPa)×0.0926 according to ISO 14577-1) is formed on the surface of a rubber layer, wherein the rubber layer is non-adhesive to a mating material.

### Means for Solving the Problem

The above object of the present invention can be achieved by a rubber-laminated sealing valve comprising a fluororubber layer and an amorphous carbon film that are sequentially laminated, wherein the amorphous carbon film is formed by a CVD plasma treatment method that supplies a high-frequency power from a high-frequency power source using hydrocarbon gas.

### Effect of the Invention

The rubber-laminated sealing valve according to the present invention exhibits such excellent non-adhesiveness that the adhesiveness of the rubber layer to a mating material is half (50%) or less of an untreated rubber layer, because an amorphous carbon film is formed by a CVD plasma treatment method using hydrocarbon gas.

Moreover, the heat resistance of the valve of the present invention is equivalent to or higher than that of PTFE resin. Furthermore, since silicon is not contained, the valve of the present invention can be used for silicone-free applications.

### EMBODIMENTS FOR CARRYING OUT THE INVENTION

Examples of the sealing valve include those made of a metal, such as stainless steel, aluminum, or brass, or those made of a resin, such as polybutylene terephthalate, polyamide, or polyphenylene sulfide, all of which have a cylindrical shape or the like, and are used to seal various gases and liquids. Specific examples thereof include CNG valves (compression natural gas valves), injector valves, city gas valves, water tank relief valves, hydrogen regulator valves, and the like. Other examples include general solenoid valves.

For the bonding between a metal or resin and a fluororubber, of the sealing valve, an adhesive layer is generally formed on the metal or resin of the sealing part. Any adhesives can be used without limitation, as long as they can bond the fluororubber. Examples thereof include silane-based adhesives for fluororubber, which are commercially available as Chemlok AP-133 (produced by Lord Far East Inc.), Metalock S-2 (produced by Toyokagaku Kenkyusho Co., Ltd.), and Megum 3290-1 (produced by Rohm and Haas Company); silane-based adhesives containing an organometallic compound; and the like. The adhesive is applied to the metal or resin, which has preferably been subjected to degreasing treatment, by a method such as dipping, spraying, or brushing so that the base weight is about 10 to 1,000 mg/m². After the applied adhesive is dried at room temperature, baking treatment is performed at about 100 to 250° C. for about 1 to 20 minutes.

Any type of fluororubber can be used, regardless of the type of crosslinkable group; however, polyol-crosslinkable fluororubber, amine-crosslinkable fluororubber, and peroxide-crosslinkable fluororubber can be preferably used. Generally used fluororubber is one that can produce a rubber layer having a hardness (durometer A; instant) of 60 to 90, preferably 70 to 80 (according to JIS K6253: 1997 corresponding to ISO 48), and a compression set (100° C., 22 hours) of 50% or less (according to JIS K6262: 2006 corresponding to ISO 815). Moreover, the content of the formulation is not particularly limited. For example, the fluororubber compounds of Formulation Examples I to III that are described later can be used.

Examples of the polyol-crosslinkable fluororubber generally include a copolymer of vinylidene fluoride and at least one of other fluorine-containing olefins, such as hexafluoropropene, pentafluoropropene, tetrafluoroethylene, trifluorochloroethylene, vinyl fluoride, and perfluoro (methyl vinyl ether); a copolymer of a fluorine-containing olefin and propylene; and the like. Such fluororubber is subjected to polyol-crosslinking using a polyol-based crosslinking agent, preferably a polyol-based crosslinking agent and a crosslinking accelerator.

Examples of usable polyol-based crosslinking agents include 2,2-bis(4-hydroxyphenyl)propane [bisnol A], 2,2-bis(4-hydroxyphenyl)perfluoropropane [bisphenol AF], bis(4-hydroxyphenyl) sulfone [bisphenol S], 2,2-bis(4-hydroxyphenyl)methane [bisphenol F], bisphenol A-bis(diphenyl phosphate), 4,4′-dihydroxydiphenyl, 2,2-bis(4-hydroxyphenyl)butane, and the like. Bisphenol A, bisphenol AF, and the others are preferably used. These polyol-based crosslinking agents may be in the form of alkali metal salts or alkaline earth metal salts. The polyol-based crosslinking agent can be used usually in a proportion of about 0.5 to 15 parts by weight, preferably about 0.5 to 6 parts by weight, based on 100 parts by weight of the fluororubber.

As the crosslinking accelerator, a quaternary phosphonium salt, an equimolar compound of a quaternary phosphonium salt and an active hydrogen-containing aromatic compound, or the like is used; a quaternary phosphonium salt is preferably used. The quaternary phosphonium salts are compounds represented by the following general formula:

(R₁R₂R₃R₄P)⁺X

where R₁ to R₄ are alkyl groups having 1 to 25 carbon atoms, alkoxyl groups, aryl groups, alkylaryl groups, aralkyl groups or polyoxyalkylene groups, two or three of which may form a heterocyclic structure together with N or P, and X is an anion of Cl⁻, Br⁻, I⁻, HSO₄⁻, H₂PO₄⁻, RCOO⁻, ROSO₂⁻, CO₃⁻⁻, etc., and include, for example, tetraphenylphosphonium chloride, benzyltriphenylphosphonium bromide, benzyltriphenylphosphonium chloride, trioctylbenzyphosphonium chloride, trioctylmethylphosphonium chloride, trioctylethylphosphonium acetate, tetraoctylphosphonium chloride, etc.

Such a quaternary phosphonium salt is used in a proportion of about 0.1 to 10 parts by weight, preferably about 0.5 to 5 parts by weight, based on 100 parts by weight of the fluororubber.

Examples of the amine-crosslinkable fluororubber include a terpolymer of tetrafluoroethylene, perfluoro(lower alkyl vinyl ether) or perfluoro(lower alkoxy-lower alkyl vinyl ether), and a cyano group-containing (perfluorovinyl ether), wherein the cyano group-containing (perfluorovinyl ether) is represented, for example, by the general formula:

CF₂═CFO(CF₂)ₙCN n: 2 to 12

CF₂═CFO[CF₂CF(CF₃)O]ₙCF₂CF(CF₃)CN n: 0 to 4

CF₂═CFO[CF₂CF(CF₃)O]ₘ(CF₂)ₙCN n: 1 to 4 m: 1 or 2

CF₂═CFO(CF₂)ₙOCF(CF₃)CN n: 2 to 5

CF₂═CF[OCF₂CF(CF₃)]ₙ,CN n: 1 to 5

As a crosslinking agent therefor, a bis(aminophenyl) compound, a bis(aminothiophenol) compound, or the like is used (Patent Documents 9 to 12).

Other examples of the amine-crosslinkable fluororubber include a copolymer obtained by copolymerizing a fluorine-containing diene compound with a copolymer of vinylidene fluoride and fluorine-containing monoolefin, such as a vinylidene fluoride-hexafluoropropylene-tetrafluoroethylene terpolymer, a vinylidene fluoride-hexafluoropropylene copolymer, or a tetrafluoroethylene-perfluoro(alkyl vinyl ether) copolymer. This fluororubber is crosslinked with a bis(aminophenyl) compound mentioned above (Patent Document 13).

Moreover, examples of the peroxide-crosslinkable fluororubber include fluororubber containing iodine and/or bromine in the molecule. The fluororubber is crosslinked with an organic peroxide that is generally used in the peroxide crosslinking.

Examples of the organic peroxide include dicumyl peroxide, cumene hydroperoxide, p-methane hydroperoxide, 2,5-dimethylhexane-2,5-dihydroperoxide, di-tert-butyl peroxide, benzoyl peroxide, m-toluyl peroxide, 2,5-dimethyl-2,5-di(tert-butylperoxy) hexane, 2,5-dimethyl-2,5-di(tert-butylperoxy) hexyne-3, 1,3-di(tert-butylperoxyisopropyl) benzene, 2,5-dimethyl-2,5-dibenzoylperoxy hexane, (1,1,3,3-tetramethylbutylperoxy) 2-ethylhexanoate, tert-butyl peroxy benzoate, tert-butyl peroxy laurate, di(tert-butylperoxy) adipate, di(2-ethoxyethylperoxy) dicarbonate, bis-(4-tert-butylcyclohexylperoxy) dicarbonate, and the like. Such an organic peroxide is used in a proportion of 0.5 to 10 parts by weight, preferably 1 to 5 parts by weight, based on 100 parts by weight of peroxide-crosslinkable fluororubber.

For the peroxide crosslinking by the organic peroxide, it is preferable to use a polyfunctional unsaturated compound in combination. As the polyfunctional unsaturated compound, a polyfunctional unsaturated compound that improves mechanical strength, compression set, etc., such as tri(meth)allyl isocyanurate, tri(meth)allyl cyanurate, triallyl trimellitate, N,N′-m-phenylene bismaleimide, diallyl phthalate, tris(diallylamine)-s-triazine, triallyl phosphite, ethyleneglycol di(meth)acrylate, diethyleneglycol di(meth)acrylate, neopentylglycol di(meth)acrylate, trimethylolpropane tri(meth)acrylate, 1,3-polybutadiene, and the like is used in a proportion of about 0.1 to 20 parts by weight, preferably about 0.5 to 10 parts by weight, based on 100 parts by weight of the peroxide-crosslinkable fluororubber. Here, (meth)allyl refers to allyl or methallyl. Similarly, (meth)acrylate refers to acrylate or methacrylate.

### FORMULATION EXAMPLE I

| | | |
|---|---|---|
| Fluororubber (Viton E45, produced by DuPont) | 100 | parts by weight |
| Calcium metasilicate | 40 | parts by weight |
| (produced by NYCO Minerals) | | |
| MT carbon black (produced by Cancarb Limited) | 2 | parts by weight |
| Magnesium oxide (Magnesia #150, produced by | 6 | parts by weight |
| Kyowa Chemical Industry Co., Ltd.) | | |
| Calcium hydroxide | 3 | parts by weight |
| (produced by Ohmi Chemical Industry Co., Ltd.) | | |
| Crosslinking agent (Curative #30, | 2 | parts by weight |
| produced by DuPont) | | |
| Crosslinking accelerator (Curative #20, | 1 | part by weight |
| produced by DuPont) | | |

### FORMULATION EXAMPLE II

| | | |
|---|---|---|
| Fluororubber (Viton E60C, produced by DuPont) | 100 | parts by weight |
| MT carbon black (produced by Cancarb Limited) | 30 | parts by weight |
| Magnesium oxide (Magnesia #30, produced by | 10 | parts by weight |
| Kyowa Chemical Industry Co., Ltd.) | | |
| Crosslinking agent (Diak No. 3, | 3 | Parts by weight |
| produced by DuPont) | | |

### FORMULATION EXAMPLE III

| | | |
|---|---|---|
| Fluororubber (Daiel G901, produced by | 100 | parts by weight |
| Daikin Industries, Ltd.) | | |
| Calcium metasilicate | 20 | parts by weight |
| (produced by NYCO Minerals) | | |
| MT carbon black (produced by Cancarb Limited) | 20 | parts by weight |
| Magnesium oxide (Magnesia #150) | 6 | parts by weight |
| Calcium hydroxide | 3 | parts by weight |
| (produced by Ohmi Chemical Industry Co., Ltd.) | | |
| Triallyl isocyanurate | 1.8 | parts by weight |
| (produced by Nippon Kasei Chemical Co., Ltd.) | | |
| Organic peroxide (Perhexa 25B, produced by | 0.8 | parts by weight |
| NOF Corporation) | | |

An amorphous carbon film is formed by a plasma CVD method on the outer surface of a rubber layer formed on the metal via an adhesive layer. Plasma CVD treatment is performed using unsaturated or saturated hydrocarbon gas under conditions that the film thickness of the amorphous carbon film becomes about 70 to 2000 nm, preferably about 200 to 1000 nm. This film thickness greatly affects the non-adhesiveness of the rubber-laminated valve.

As the method for forming an amorphous carbon film, known methods can be used as they are. For example, a rubber-laminated sealing valve is placed on an electrode in a vacuum chamber of a low-pressure plasma treatment device, and the vacuum chamber is evacuated to a degree of vacuum of about 5 to 50 Pa. Then, hydrocarbon gas is introduced into the vacuum chamber until the degree of vacuum is about 6 to 100 Pa. While maintaining the pressure in the vacuum chamber at about 6 to 100 Pa, a high-frequency power with an output of, for example, about 10 to 3000 W is supplied from a high-frequency power source with a frequency of 40 kHz or 13.56 MHz, although the output range is not limited because it depends on the size of the device. A high-frequency voltage is applied for about 1 to 60 minutes, preferably about 5 to 10 minutes, to convert the hydrocarbon gas into plasma, thereby forming an amorphous hydrocarbon film on the rubber-laminated sealing valve.

Examples of usable hydrocarbon gas include unsaturated hydrocarbon gas, such as acetylene, ethylene, and propylene; and saturated hydrocarbon gas, such as methane, ethane, and propane. Acetylene, ethylene, or propylene is preferably used as the unsaturated hydrocarbon gas in terms of non-adhesiveness. Further, methane is preferably used as the saturated hydrocarbon gas.

The amorphous carbon film to be formed has an indenter hardness of 5 GPa or more, which corresponds to a Vickers hardness of about Hv 500 or more, generally a hardness of 5 to 20 GPa. The film thickness thereof is about 70 nm or more, preferably about 200 nm or more.

In the present invention, an amorphous carbon film may be formed on the outer surface of the rubber layer. The present invention includes all of a product in which an amorphous carbon film is directly formed on the rubber surface without performing a pretreatment, such as termination treatment, a product in which plasma modification treatment is previously applied to the rubber surface before an amorphous carbon film is formed, and a product in which an intermediate layer film is provided between the rubber and the amorphous carbon film; however, preferably used in terms of the simplification of the structure, etc., is a product in which an amorphous carbon film is directly formed on the rubber surface without providing an intermediate layer film.

### EXAMPLES

The following describes the present invention with reference to Examples.

### Example 1

After a SUS304 cylindrical metallic part was degreased with methyl ethyl ketone, a silane-based adhesive (Chemlok AP-133, produced by Lord Far East Inc.) was applied to the outer surface of the cylindrical metallic part, and dried at room temperature. Then, baking treatment was carried out at about 150 to 230° C. for about 0.5 to 30 minutes. Subsequently, the fluororubber compound of Formulation Example I mentioned above was molded by press crosslinking at 170° C. for 15 minutes and oven crosslinking (secondary crosslinking) at 200° C. for 24 hours, thereby obtaining a fluororubber-laminated sealing valve sample.

Next, rubber-laminated valve sample was placed on a lower electrode in a vacuum chamber of a low-pressure plasma treatment device so that the rubber surface turned upward, and the vacuum chamber was evacuated to a degree of vacuum of 10 Pa. Acetylene gas was introduced into the vacuum chamber until the degree of vacuum was 20 Pa. While maintaining the pressure in the vacuum chamber at about 20 Pa, a high-frequency power with an output of 900 W was supplied from a high-frequency (40 kHz) power source, by which a high-frequency voltage was applied to the lower electrode for 10 minutes, to convert the acetylene gas into a plasma, thereby forming an amorphous carbon film on the rubber-metal laminated plate.

In the low-pressure plasma CVD treatment device used herein, an upper electrode and a lower electrode were placed, respectively, in the upper side and lower side of the inside of a vacuum chamber providing a gas supply portion and a gas discharge device on the outer side surface thereof The lower electrode was connected to the high-frequency power source disposed outside the vacuum chamber, and a ground wire was arranged from the upper electrode to the outside of the vacuum chamber. Further, as a test piece for evaluation, a silicon wafer test piece in which similar amorphous carbon film was formed on the surface thereof was also prepared in the chamber.

The non-adhesiveness and film thickness of the fluororubber-laminated sealing valve in which an amorphous carbon film was formed on the surface thereof were measured. Further, since it was difficult to evaluate some properties on a rubber base material due to the influence of the elasticity of the base material, an amorphous carbon film was produced using a silicon wafer (Polished Wafer, produced by SUMCO Corporation) in place of the base material under the same conditions as those for the rubber base material, and the property (film hardness) of the carbon film was evaluated.

Non-adhesiveness: A 5/16-inch brass ball was pressed to the fluororubber-laminated sealing valve with a load of 20 N, and this state was maintained in a thermohygrostat at 80° C. and 95% RH for 120 hours. After releasing the load and cooling to room temperature, the power to pull the brass ball when the brass ball was pulled from the rubber surface was measured by using a load cell (LUR-A-50NSA1, produced by Kyowa Electronic Instruments Co., Ltd.) and a moving strain dynamic strain measuring device (DPM-600, produced by Kyowa Electronic Instruments Co., Ltd.). The contact area of the brass ball pressed to the rubber was confirmed by a microscope, and the power (N) to separate them was calculated as adhesive power (unit: MPa).

An adhesiveness of 0.2 MPa or less can be regarded as non-adhesiveness.

Film thickness: The rubber portion of the fluororubber-laminated sealing valve was cut, and the cross-section was exposed. Then, the cross-section was converted to a mirror surface by a Thin Film • Cross Section Polisher (CP) (produced by JEOL Ltd.), and the film thickness was determined by FE-SEM (SU8220) (produced by Hitachi, Ltd.).

Film hardness: Using a Nano Indenter G200 (produced by Agilent Technologies), the silicon wafer test piece was pressed to a depth of 200 nm by CSM measurement with an amplitude of 2 nm and a strain of 0.05/sec, and the coating hardness of the amorphous carbon film on the silicon wafer at a depth of 50 nm was calculated.

### Example 2

In Example 1, the low-pressure plasma treatment was performed while changing the applied power from 900 W to 200 W.

### Example 3

In Example 1, the low-pressure plasma treatment was performed while changing acetylene gas to ethylene gas.

### Example 4

In Example 3, the low-pressure plasma treatment was performed while changing the applied power from 900 W to 200 W.

### Example 5

In Example 3, the low-pressure plasma treatment was performed while changing the applied time from 10 min. to 5 min.

### Example 6

In Example 4, the low-pressure plasma treatment was performed while changing the applied time from 10 min. to 5 min.

### Example 7

In Example 1, the low-pressure plasma treatment was performed while changing acetylene gas to propylene gas.

### Example 8

In Example 7, the low-pressure plasma treatment was performed while changing the applied power from 900 W to 200 W.

### Example 9

In Example 1, the low-pressure plasma treatment was performed while changing acetylene gas to methane gas.

### Example 10

In Example 9, the low-pressure plasma treatment was performed while changing the applied power from 900 W to 200 W.

### Example 11

In Example 1, as a fluororubber composition, the compound of Formulation Example II was used.

### Example 12

In Example 1, as a fluororubber composition, the compound of Formulation Example III was used.

### Comparative Example

In Example 1, a low pressure plasma treatment was not used.

Measurement results of the foregoing Examples and Comparative Example are shown in the following Table.

TABLE

| | Fluororubber-laminated valve | | Silicon wafer |
|---|---|---|---|
| | Adhesive power | Film thickness | Film hardness |
| Example | (MPa) | (nm) | (GPa) |
| Ex. 1 | 0.068 | 587 | 15 |
| Ex. 2 | 0.082 | 559 | 10 |
| Ex. 3 | 0.075 | 478 | 17 |
| Ex. 4 | 0.084 | 253 | 10 |
| Ex. 5 | 0.066 | 249 | 17 |
| Ex. 6 | 0.18 | 141 | 10 |
| Ex. 7 | 0.065 | 455 | 17 |
| Ex. 8 | 0.12 | 253 | 9.0 |
| Ex. 9 | 0.11 | 104 | 14 |
| Ex. 10 | 0.14 | 73 | 13 |
| Ex. 11 | 0.070 | 590 | 15 |
| Ex. 12 | 0.065 | 593 | 15 |
| Comparative Ex. | 0.39 | — | — |

1. A rubber-laminated sealing valve comprising a fluororubber layer and an amorphous carbon film that are sequentially laminated, wherein the amorphous carbon film is formed by a CVD plasma treatment method that supplies a high-frequency power from a high-frequency power source using hydrocarbon gas.

2. The rubber-laminated sealing valve according to claim 1, wherein the hydrocarbon gas is unsaturated or saturated hydrocarbon gas.

3. The rubber-laminated sealing valve according to claim 2, wherein the unsaturated or saturated hydrocarbon gas is acetylene, ethylene, propylene, or methane.

4. The rubber-laminated sealing valve according to claim 1, wherein the amorphous carbon film has an indenter hardness of 5 GPa or more.

5. The rubber-laminated sealing valve according to claim 1, wherein the amorphous carbon film has a film thickness of 70 to 2000 nm.

6. The rubber-laminated sealing valve according to claim 1, wherein the fluororubber layer is a layer of a crosslinked product of polyol-crosslinkable rubber, amine-crosslinkable rubber, or peroxide-crosslinkable rubber.
